(19) United States
(12) Patent Application Publication
(10) Pub. No.: US 2024/0201486 A1
(43) Pub. Date: Jun. 20, 2024

(54) CONTROLLING ABERRATION IN AN OPTICAL SYSTEM, A METROLOGY SYSTEM, LITHOGRAPHIC APPARATUS, AND METHODS THEREOF

(71) Applicant: ASML Netherlands B.V., Veldhoven (NL)

(72) Inventors: Krishanu SHOME, Cheshire, CT (US); Scott Douglas COSTON, New Milford, CT (US); Kan DU, Milford, CT (US)

(73) Assignee: ASML Netherlands B.V., Veldhoven (NL)

(21) Appl. No.: 18/556,801

(22) PCT Filed: Mar. 31, 2022
(86) PCT No.: PCT/EP2022/058678

§ 371 Date: Oct. 23, 2023

Related U.S. Application Data
(60) Provisional application No. 63/178,756, filed on Apr. 23, 2021.

(51) Int. Cl. G02B 27/00; G03F 7/00; G03F 7/16

(52) U.S. Cl. CPC G02B 27/0025; G03F 7/168; G03F 7/70266; G03F 7/70325; G03F 7/706

(57) ABSTRACT

A method includes determining optical aberrations of an optical system, identifying an illumination profile that compensates for the optical aberrations of the optical system, and curing a layer of optical cement of an optical device using a modulated energy beam to achieve the identified illumination profile.

### CROSS-REFERENCE TO RELATED APPLICATIONS

This application claims priority of U.S. Provisional Patent Application No. 63/178,756, which was filed on Apr. 23, 2021, and which is incorporated herein in its entirety by reference.

### FIELD

The present disclosure relates to methods and systems for controlling aberrations in an optical system, for example, an alignment sensor.

### BACKGROUND

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, can be used to generate a circuit pattern to be formed on an individual layer of the IC. This pattern can be transferred onto a target portion (e.g., comprising part of, one, or several dies) on a substrate (e.g., a silicon wafer). Transfer of the pattern is typically via imaging onto a layer of radiation-sensitive material (resist) provided on the substrate. In general, a single substrate will contain a network of adjacent target portions that are successively patterned. Known lithographic apparatus include so-called steppers, in which each target portion is irradiated by exposing an entire pattern onto the target portion at one time, and so-called scanners, in which each target portion is irradiated by scanning the pattern through a radiation beam in a given direction (the “scanning”-direction) while synchronously scanning the target portions parallel or anti-parallel to this scanning direction. It is also possible to transfer the pattern from the patterning device to the substrate by imprinting the pattern onto the substrate.

During lithographic operation, different processing steps may require different layers to be sequentially formed on the substrate. Sequencing of layers is typically accomplished by exchanging different reticles, according to the desired pattern for each layer, for each pattern transfer process. A typical lithographic system works within sub-nanometer tolerances regarding patterns on the reticle and patterns transferred onto the wafer from the reticle. Therefore, it is desirable to improve the wavefront control in alignment and overlay sensors to achieve a sub-nanometer budget or tolerance.

### SUMMARY

There is a need to provide improved wavefront control techniques in an optical system.

In some embodiments, a method includes determining optical aberrations of an optical system, identifying an illumination profile that compensates for the optical aberrations of the optical system, and curing a layer of optical cement of an optical device using a modulated energy beam to achieve the identified illumination profile.

In some embodiments, a system comprises a processor, an optical system, and an illumination system. The processor is configured to determine optical aberrations of an optical system and identify an illumination profile that compensates for the optical aberrations of the optical system. The illumination system is configured to generate an energy beam, modulate the energy beam with the illumination profile, and cure a layer of optical cement of an optical device of the optical system with the energy beam.

In some embodiments, a lithography apparatus comprises an illumination apparatus, a projection system, and an optical system. The illumination apparatus is configured to illuminate a pattern of a patterning device. The projection system configured to project an image of the pattern onto a substrate. The optical system includes an illumination system, an optical device, and processing circuitry. The illumination system is configured to generate an energy beam having an illumination profile determined based on optical aberrations of the optical system and to illuminate an optical device with the energy beam. The optical device is deposited in an optical path of the optical system. The optical device includes a layer of optical cement cured using the beam. The processing circuitry is configured to determine the illumination profile based on the optical aberrations of the optical system.

Further features of the present disclosure, as well as the structure and operation of various embodiments, are described in detail below with reference to the accompanying drawings. It is noted that the present disclosure is not limited to the specific embodiments described herein. Such embodiments are presented herein for illustrative purposes only. Additional embodiments will be apparent to persons skilled in the relevant art(s) based on the teachings contained herein.

### BRIEF DESCRIPTION OF THE DRAWINGS/FIGURES

The accompanying drawings, which are incorporated herein and form part of the specification, illustrate the present disclosure and, together with the description, further serve to explain the principles of the present disclosure and to enable a person skilled in the relevant art(s) to make and use embodiments described herein.

FIG. 1A illustrates a reflective lithographic apparatus, according to some embodiments.

FIG. 1B illustrates a transmissive lithographic apparatus, according to some embodiments.

FIG. 2 illustrates a more detailed schematic of the reflective lithographic apparatus, according to some embodiments.

FIG. 3 illustrates a lithographic cell, according to some embodiments.

FIG. 4 illustrates alignment apparatuses, according to some embodiments.

FIG. 5 illustrates an illumination profile, according to some embodiments.

FIG. 6 illustrates a wavefront interferogram resulting from the illumination profile, according to some embodiments.

FIG. 7 illustrates a system for aberration control, according to some embodiments.

FIG. 8 illustrates an alignment apparatus, according to some embodiments.

FIG. 9 illustrates method steps for performing a method including functions described herein, according to some embodiments.

The features of the present disclosure will become more apparent from the detailed description set forth below when taken in conjunction with the drawings, in which like reference characters identify corresponding elements throughout. In the drawings, like reference numbers generally indicate identical, functionally similar, and/or structurally similar elements. Additionally, generally, the left-most digit(s) of a reference number identifies the drawing in which the reference number first appears. Unless otherwise indicated, the drawings provided throughout the disclosure should not be interpreted as to-scale drawings.

### DETAILED DESCRIPTION

This specification discloses one or more embodiments that incorporate the features of the present disclosure. The disclosed embodiment(s) are provided as examples. The scope of the present disclosure is not limited to the disclosed embodiment(s). Claimed features are defined by the claims appended hereto.

The embodiment(s) described, and references in the specification to “one embodiment,” “an embodiment,” “an example embodiment,” etc., indicate that the embodiment(s) described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to effect such feature, structure, or characteristic in connection with other embodiments whether or not explicitly described.

Spatially relative terms, such as “beneath,” “below,” “lower,” “above,” “on,” “upper” and the like, can be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus can be otherwise oriented (rotated 90 degrees or at other orientations) and the spatially relative descriptors used herein may likewise be interpreted accordingly.

The term “about” as used herein indicates the value of a given quantity that can vary based on a particular technology. Based on the particular technology, the term “about” can indicate a value of a given quantity that varies within, for example, 10-30% of the value (e.g., +10%, +20%, or +30% of the value).

Embodiments of the disclosure can be implemented in hardware, firmware, software, or any combination thereof. Embodiments of the disclosure may also be implemented as instructions stored on a machine-readable medium, which can be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Further, firmware, software, routines, and/or instructions can be described herein as performing certain actions. However, it should be appreciated that such descriptions are merely for convenience and that such actions in fact result from computing devices, processors, controllers, or other devices executing the firmware, software, routines, instructions, etc. The term “non-transitory” may be used herein to characterize computer readable media used for storing data, information, instructions, and the like, with the sole exception being a transitory, propagating signal.

Before describing such embodiments in more detail, however, it is instructive to present an example environment in which embodiments of the present disclosure can be implemented.

### Example Lithographic Systems

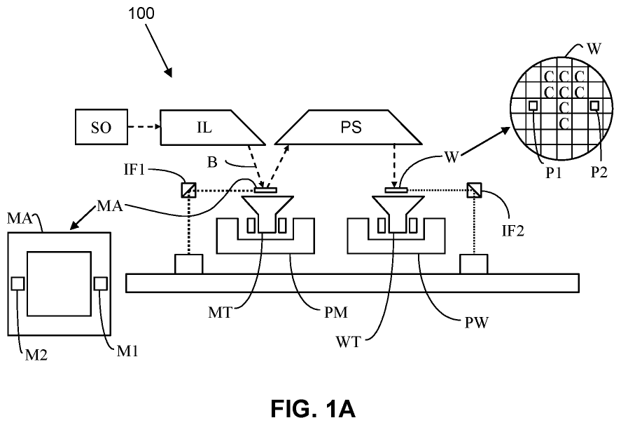

FIGS. 1A and 1B show schematic illustrations of a lithographic apparatus 100 and lithographic apparatus 100′, respectively, in which embodiments of the present disclosure may be implemented. Lithographic apparatus 100 and lithographic apparatus 100′ each include the following: an illumination system (illuminator) IL configured to condition a radiation beam B (for example, deep ultra violet or extreme ultra violet radiation); a support structure (for example, a mask table) MT configured to support a patterning device (for example, a mask, a reticle, or a dynamic patterning device) MA and connected to a first positioner PM configured to accurately position the patterning device MA; and, a substrate table (for example, a wafer table) WT configured to hold a substrate (for example, a resist coated wafer) W and connected to a second positioner PW configured to accurately position the substrate W. Lithographic apparatus 100 and 100′ also have a projection system PS configured to project a pattern imparted to the radiation beam B by patterning device MA onto a target portion (for example, comprising one or more dies) C of the substrate W. In lithographic apparatus 100, the patterning device MA and the projection system PS are reflective. In lithographic apparatus 100′, the patterning device MA and the projection system PS are transmissive.

The illumination system IL may include various types of optical components, such as refractive, reflective, catadioptric, magnetic, electromagnetic, electrostatic, or other types of optical components, or any combination thereof, for directing, shaping, or controlling the radiation beam B.

The support structure MT holds the patterning device MA in a manner that depends on the orientation of the patterning device MA with respect to a reference frame, the design of at least one of the lithographic apparatus 100 and 100′, and other conditions, such as whether or not the patterning device MA is held in a vacuum environment. The support structure MT may use mechanical, vacuum, electrostatic, or other clamping techniques to hold the patterning device MA. The support structure MT may be a frame or a table, for example, which may be fixed or movable, as required. By using sensors, the support structure MT may ensure that the patterning device MA is at a desired position, for example, with respect to the projection system PS.

The term “patterning device” MA should be broadly interpreted as referring to any device that may be used to impart a radiation beam B with a pattern in its cross-section, such as to create a pattern in the target portion C of the substrate W. The pattern imparted to the radiation beam B may correspond to a particular functional layer in a device being created in the target portion C to form an integrated circuit.

The patterning device MA may be transmissive (as in lithographic apparatus 100′ of FIG. 1B) or reflective (as in lithographic apparatus 100 of FIG. 1A). Examples of patterning devices MA include reticles, masks, programmable mirror arrays, or programmable LCD panels. Masks are well known in lithography, and include mask types such as binary, alternating phase shift, or attenuated phase shift, as well as various hybrid mask types. An example of a programmable mirror array employs a matrix arrangement of small mirrors, each of which may be individually tilted so as to reflect an incoming radiation beam in different directions. The tilted mirrors impart a pattern in the radiation beam 20 B, which is reflected by a matrix of small mirrors.

The term “projection system” PS may encompass any type of projection system, including refractive, reflective, catadioptric, magnetic, electromagnetic and electrostatic optical systems, or any combination thereof, as appropriate for the exposure radiation being used, or for other factors, such as the use of an immersion liquid on the substrate W or the use of a vacuum. A vacuum environment may be used for EUV or electron beam radiation since other gases may absorb too much radiation or electrons. A vacuum environment may therefore be provided to the whole beam path with the aid of a vacuum wall and vacuum pumps.

Lithographic apparatus 100 and/or lithographic apparatus 100′ may be of a type having two (dual stage) or more substrate tables WT (and/or two or more mask tables). In such “multiple stage” machines, the additional substrate tables WT may be used in parallel, or preparatory steps may be carried out on one or more tables while one or more other substrate tables WT are being used for exposure. In some situations, the additional table may not be a substrate table WT.

The lithographic apparatus may also be of a type wherein at least a portion of the substrate may be covered by a liquid having a relatively high refractive index, e.g., water, so as to fill a space between the projection system and the substrate. An immersion liquid may also be applied to other spaces in the lithographic apparatus, for example, between the mask and the projection system. Immersion techniques are well known in the art for increasing the numerical aperture of projection systems. The term “immersion” as used herein does not mean that a structure, such as a substrate, must be submerged in liquid, but rather only means that liquid is located between the projection system and the substrate during exposure.

Referring to FIGS. 1A and 1B, the illuminator IL receives a radiation beam from a radiation source SO. The source SO and the lithographic apparatus 100, 100′ may be separate physical entities, for example, when the source SO is an excimer laser. In such cases, the source SO is not considered to form part of the lithographic apparatus 100 or 100′, and the radiation beam B passes from the source SO to the illuminator IL with the aid of a beam delivery system BD (in FIG. 1B) including, for example, suitable directing mirrors and/or a beam expander. In other cases, the source SO may be an integral part of the lithographic apparatus 100, 100′, for example, when the source SO is a mercury lamp. The source SO and the illuminator IL, together with the beam delivery system BD, if required, may be referred to as a radiation system.

The illuminator IL may include an adjuster AD (in FIG. 1B) for adjusting the angular intensity distribution of the radiation beam. Generally, at least the outer and/or inner radial extent (commonly referred to as “σ-outer” and “σ-inner,” respectively) of the intensity distribution in a pupil plane of the illuminator may be adjusted. In addition, the illuminator IL may comprise various other components (in FIG. 1B), such as an integrator IN and a condenser CO. The illuminator IL may be used to condition the radiation beam B to have a desired uniformity and intensity distribution in its cross section.

Referring to FIG. 1A, the radiation beam B is incident on the patterning device (for example, mask) MA, which is held on the support structure (for example, mask table) MT, and is patterned by the patterning device MA. In lithographic apparatus 100, the radiation beam B is reflected from the patterning device (for example, mask) MA. After being reflected from the patterning device (for example, mask) MA, the radiation beam B passes through the projection system PS, which focuses the radiation beam B onto a target portion C of the substrate W. With the aid of the second positioner PW and position sensor IF2 (for example, an interferometric device, linear encoder, or capacitive sensor), the substrate table WT may be moved accurately (for example, so as to position different target portions C in the path of the radiation beam B). Similarly, the first positioner PM and another position sensor IF1 may be used to accurately position the patterning device (for example, mask) MA with respect to the path of the radiation beam B. Patterning device (for example, mask) MA and substrate W may be aligned using mask alignment marks M1, M2 and substrate alignment marks P1, P2.

Referring to FIG. 1B, the radiation beam B is incident on the patterning device (for example, mask MA), which is held on the support structure (for example, mask table MT), and is patterned by the patterning device. Having traversed the mask MA, the radiation beam B passes through the projection system PS, which focuses the beam onto a target portion C of the substrate W. The projection system has a pupil conjugate PPU to an illumination system pupil IPU. Portions of radiation emanate from the intensity distribution at the illumination system pupil IPU and traverse a mask pattern without being affected by diffraction at the mask pattern and create an image of the intensity distribution at the illumination system pupil IPU.

The projection system PS projects an image MP′ of the mask pattern MP, where image MP′ is formed by diffracted beams produced from the mark pattern MP by radiation from the intensity distribution, onto a photoresist layer coated on the substrate W. For example, the mask pattern MP may include an array of lines and spaces. A diffraction of radiation at the array and different from zeroth order diffraction generates diverted diffracted beams with a change of direction in a direction perpendicular to the lines. Undiffracted beams (i.e., so-called zeroth order diffracted beams) traverse the pattern without any change in propagation direction. The zeroth order diffracted beams traverse an upper lens or upper lens group of the projection system PS, upstream of the pupil conjugate PPU of the projection system PS, to reach the pupil conjugate PPU. The portion of the intensity distribution in the plane of the pupil conjugate PPU and associated with the zeroth order diffracted beams is an image of the intensity distribution in the illumination system pupil IPU of the illumination system IL. The aperture device PD, for example, is disposed at or substantially at a plane that includes the pupil conjugate PPU of the projection system PS.

The projection system PS is arranged to capture, by means of a lens or lens group L, not only the zeroth order diffracted beams, but also first-order or first- and higher-order diffracted beams (not shown). In some embodiments, dipole illumination for imaging line patterns extending in a direction perpendicular to a line may be used to utilize the resolution enhancement effect of dipole illumination. For example, first-order diffracted beams interfere with corresponding zeroth-order diffracted beams at the level of the wafer W to create an image of the line pattern MP at highest possible resolution and process window (i.e., usable depth of focus in combination with tolerable exposure dose deviations). In some embodiments, astigmatism aberration may be reduced by providing radiation poles (not shown) in opposite quadrants of the illumination system pupil IPU. Further, in some embodiments, astigmatism aberration may be reduced by blocking the zeroth order beams in the pupil conjugate PPU of the projection system associated with radiation poles in opposite quadrants. This is described in more detail in U.S. Pat. No. 7,511,799 B2, issued Mar. 31, 2009, which is incorporated by reference herein in its entirety.

With the aid of the second positioner PW and position sensor IF (for example, an interferometric device, linear encoder, or capacitive sensor), the substrate table WT may be moved accurately (for example, so as to position different target portions C in the path of the radiation beam B). Similarly, the first positioner PM and another position sensor (not shown in FIG. 1B) may be used to accurately position the mask MA with respect to the path of the radiation beam B (for example, after mechanical retrieval from a mask library or during a scan).

In general, movement of the mask table MT may be realized with the aid of a long-stroke module (coarse positioning) and a short-stroke module (fine positioning), which form part of the first positioner PM. Similarly, movement of the substrate table WT may be realized using a long-stroke module and a short-stroke module, which form part of the second positioner PW. In the case of a stepper (as opposed to a scanner), the mask table MT may be connected to a short-stroke actuator only or may be fixed. Mask MA and substrate W may be aligned using mask alignment marks M1, M2, and substrate alignment marks P1, P2. Although the substrate alignment marks (as illustrated) occupy dedicated target portions, they may be located in spaces between target portions (known as scribe-lane alignment marks). Similarly, in situations in which more than one die is provided on the mask MA, the mask alignment marks may be located between the dies.

Mask table MT and patterning device MA may be in a vacuum chamber V, where an in-vacuum robot IVR may be used to move patterning devices such as a mask in and out of vacuum chamber. Alternatively, when mask table MT and patterning device MA are outside of the vacuum chamber, an out-of-vacuum robot may be used for various transportation operations, similar to the in-vacuum robot IVR. Both the in-vacuum and out-of-vacuum robots need to be calibrated for a smooth transfer of any payload (e.g., mask) to a fixed kinematic mount of a transfer station.

The lithographic apparatus 100 and 100′ may be used in at least one of the following modes:

1. In step mode, the support structure (for example, mask table) MT and the substrate table WT are kept essentially stationary, while an entire pattern imparted to the radiation beam B is projected onto a target portion C at one time (i.e., a single static exposure). The substrate table WT is then shifted in the X and/or Y direction so that a different target portion C may be exposed.

2. In scan mode, the support structure (for example, mask table) MT and the substrate table WT are scanned synchronously while a pattern imparted to the radiation beam B is projected onto a target portion C (i.e., a single dynamic exposure). The velocity and direction of the substrate table WT relative to the support structure (for example, mask table) MT may be determined by the (de-)magnification and image reversal characteristics of the projection system PS.

3. In another mode, the support structure (for example, mask table) MT is kept substantially stationary holding a programmable patterning device, and the substrate table WT is moved or scanned while a pattern imparted to the radiation beam B is projected onto a target portion C. A pulsed radiation source SO may be employed and the programmable patterning device is updated as required after each movement of the substrate table WT or in between successive radiation pulses during a scan. This mode of operation may be readily applied to maskless lithography that utilizes a programmable patterning device, such as a programmable mirror array.

Combinations and/or variations on the described modes of use or entirely different modes of use may also be employed.

In some embodiments, a lithographic apparatus may generate DUV and/or EUV radiation. For example, lithographic apparatus 100′ may be configured to operate using a DUV source. In another example, lithographic apparatus 100 includes an extreme ultraviolet (EUV) source, which is configured to generate a beam of EUV radiation for EUV lithography. In general, the EUV source is configured in a radiation system, and a corresponding illumination system is configured to condition the EUV radiation beam of the EUV source.

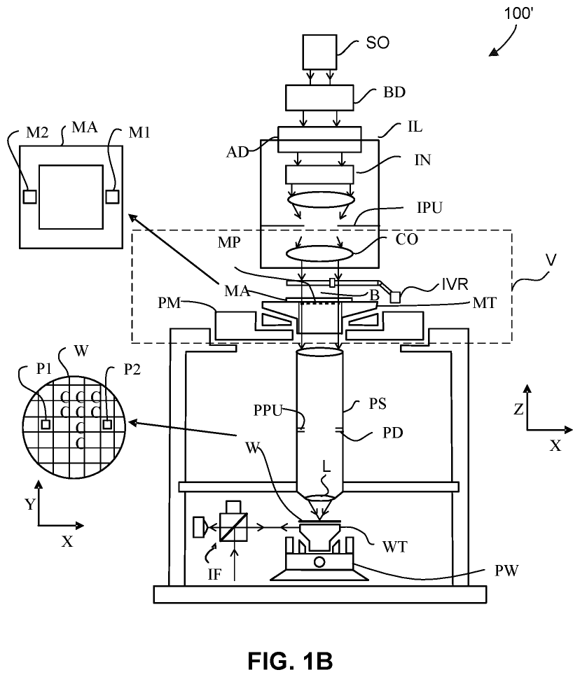

FIG. 2 shows the lithographic apparatus 100 in more detail, including the source collector apparatus SO, the illumination system IL, and the projection system PS. The source collector apparatus SO is constructed and arranged such that a vacuum environment may be maintained in an enclosing structure 220 of the source collector apparatus SO. An EUV radiation emitting plasma 210 can be formed by a discharge produced plasma source. EUV radiation may be produced by a gas or vapor, for example Xe gas, Li vapor, or Sn vapor in which the very hot plasma 210 is created to emit radiation in the EUV range of the electromagnetic spectrum. The very hot plasma 210 is created by, for example, an electrical discharge causing at least a partially ionized plasma. Partial pressures of, for example, 10 Pa of Xe, Li, Sn vapor, or any other suitable gas or vapor may be required for efficient generation of the radiation. In some embodiments, a plasma of excited tin (Sn) is provided to produce EUV radiation.

The radiation emitted by the hot plasma 210 is passed from a source chamber 211 into a collector chamber 212 via an optional gas barrier or contaminant trap 230 (in some cases also referred to as contaminant barrier or foil trap), which is positioned in or behind an opening in source chamber 211. The contaminant trap 230 can include a channel structure. Contamination trap 230 can also include a gas barrier or a combination of a gas barrier and a channel structure. The contaminant trap or contaminant barrier 230 further indicated herein at least includes a channel structure.

The collector chamber 212 can include a radiation collector CO, which may be a so-called grazing incidence collector. Radiation collector CO has an upstream radiation collector side 251 and a downstream radiation collector side 252. Radiation that traverses collector CO may be reflected off a grating spectral filter 240 to be focused in a virtual source point IF. The virtual source point IF is commonly referred to as the intermediate focus, and the source collector apparatus is arranged such that the intermediate focus IF is located at or near an opening 219 in the enclosing structure 220. The virtual source point IF is an image of the radiation emitting plasma 210. Grating spectral filter 240 is used in particular for suppressing infra-red (IR) radiation.

Subsequently the radiation traverses the illumination system IL, which may include a faceted field mirror device 222 and a faceted pupil mirror device 224 arranged to provide a desired angular distribution of the radiation beam 221, at the patterning device MA, as well as a desired uniformity of radiation intensity at the patterning device MA. Upon reflection of the beam of radiation 221 at the patterning device MA, held by the support structure MT, a patterned beam 226 is formed and the patterned beam 226 is imaged by the projection system PS via reflective elements 228, 229 onto a substrate W held by the wafer stage or substrate table WT.

More elements than shown may generally be present in illumination optics unit IL and projection system PS. The grating spectral filter 240 can optionally be present, depending upon the type of lithographic apparatus. Further, there may be more mirrors present than those shown in the FIG. 2, for example there may be one to six additional reflective elements present in the projection system PS than shown in FIG. 2.

Collector optic CO, as illustrated in FIG. 2, is depicted as a nested collector with grazing incidence reflectors 253, 254, and 255, just as an example of a collector (or collector mirror). The grazing incidence reflectors 253, 254, and 255 are disposed axially symmetric around an optical axis O and a collector optic CO of this type is preferably used in combination with a discharge produced plasma source, often called a DPP source.

### Exemplary Lithographic Cell

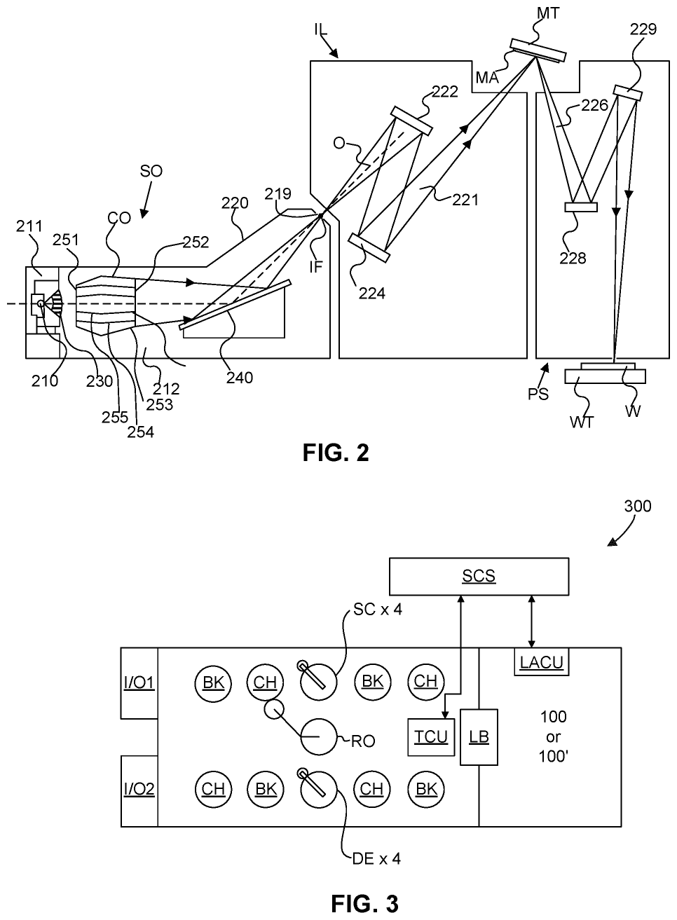

FIG. 3 shows a lithographic cell 300, also sometimes referred to a lithocell or cluster, according to some embodiments. Lithographic apparatus 100 or 100′ may form part of lithographic cell 300. Lithographic cell 300 can also include one or more apparatuses to perform pre- and post-exposure processes on a substrate. Conventionally these include spin coaters SC to deposit resist layers, developers DE to develop exposed resist, chill plates CH, and bake plates BK. A substrate handler, or robot, RO picks up substrates from input/output ports I/O1, I/O2, moves them between the different process apparatuses and delivers them to the loading bay LB of the lithographic apparatus 100 or 100′. These devices, which are often collectively referred to as the track, are under the control of a track control unit TCU, which is itself controlled by a supervisory control system SCS, which also controls the lithographic apparatus via lithography control unit LACU. Thus, the different apparatuses may be operated to maximize throughput and processing efficiency.

### Exemplary Inspection Apparatuses

In order to control the lithographic process to place device features accurately on the substrate, alignment marks are generally provided on the substrate, and the lithographic apparatus includes one or more alignment apparatuses and/or systems by which positions of marks on a substrate must be measured accurately. These alignment apparatuses are effectively position measuring apparatuses. Different types of marks and different types of alignment apparatuses and/or systems are known from different times and different manufacturers. A type of system widely used in current lithographic apparatus is based on a self-referencing interferometer as described in U.S. Pat. No. 6,961,116 (den Boef et al.), which is incorporated by reference herein in its entirety. Generally, marks are measured separately to obtain X- and Y-positions. A combined X- and Y-measurement may be performed using the techniques described in U.S. Publication No. 2009/195768 A (Bijnen et al.), which is also incorporated by reference herein in its entirety.

The terms “inspection apparatus,” “metrology apparatus,” and the like may be used herein to refer to, e.g., a device or system used for measuring a property of a structure (e.g., overlay error, critical dimension parameters) or used in a lithographic apparatus to inspect an alignment of a wafer (e.g., alignment apparatus).

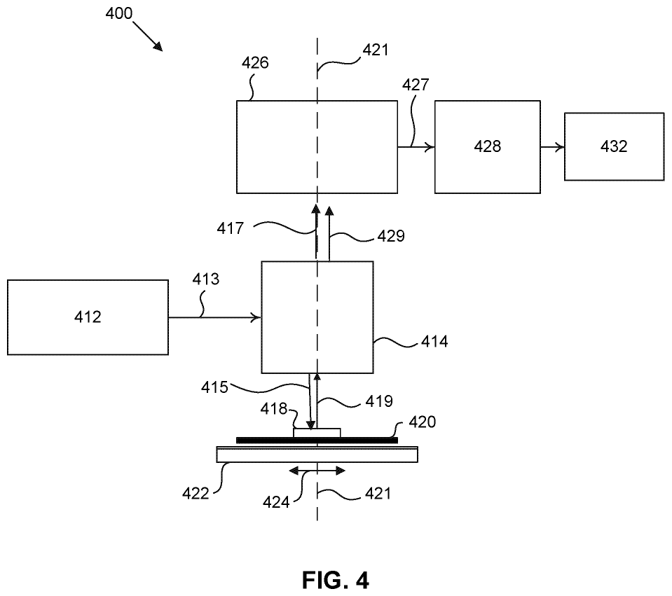

FIG. 4 shows a schematic of a cross-sectional view of a metrology apparatus 400, according to some embodiments. In some embodiments, metrology apparatus 400 can be implemented as part of lithographic apparatus 100 or 100′. Metrology apparatus 400 can be configured to align a substrate (e.g., substrate W) with respect to a patterning device (e.g., patterning device MA). Metrology apparatus 400 can be further configured to detect positions of alignment marks on the substrate and to align the substrate with respect to the patterning device or other components of lithographic apparatus 100 or 100′ using the detected positions of the alignment marks. Such alignment of the substrate may ensure accurate exposure of one or more patterns on the substrate.

In some embodiments, metrology apparatus 400 can include an illumination system 412, a beam splitter 414, an interferometer 426, a detector 428, and an overlay calculation processor 432. Illumination system 412 can be configured to provide an electromagnetic narrow band radiation beam 413 having one or more passbands. In an example, the one or more passbands may be within a spectrum of wavelengths between about 500 nm to about 900 nm. In another example, the one or more passbands may be discrete narrow passbands within a spectrum of wavelengths between about 500 nm to about 900 nm. Illumination system 412 can be further configured to provide one or more passbands having substantially constant center wavelength (CWL) values over a long period of time (e.g., over a lifetime of illumination system 412). Such configuration of illumination system 412 can help to prevent the shift of the actual CWL values from the desired CWL values, as discussed above, in current alignment systems. And, as a result, the use of constant CWL values may improve long-term stability and accuracy of alignment systems (e.g., metrology apparatus 400) compared to the current alignment apparatuses.

In some embodiments, beam splitter 414 can be configured to receive radiation beam 413 and split radiation beam 413 into at least two radiation sub-beams. For example, radiation beam 413 can be split into radiation sub-beams 415 and 417, as shown in FIG. 4. Beam splitter 414 can be further configured to direct radiation sub-beam 415 onto a substrate 420 placed on a stage 422. In one example, the stage 422 is movable along direction 424. Radiation sub-beam 415 can be configured to illuminate an alignment mark or a target 418 located on substrate 420. Alignment mark or target 418 can be coated with a radiation sensitive film. In some embodiments, alignment mark or target 418 can have one hundred and eighty degrees (i.e., 180°) symmetry. That is, when alignment mark or target 418 is rotated 180° about an axis of symmetry perpendicular to a plane of alignment mark or target 418, rotated alignment mark or target 418 can be substantially identical to an unrotated alignment mark or target 418. The target 418 on substrate 420 can be a resist layer grating comprising bars that are formed of solid resist lines, a product layer grating, a composite grating stack in an overlay target structure comprising a resist grating overlaid or interleaved on a product layer grating, or the like. The bars may alternatively be etched into the substrate. This pattern may be sensitive to chromatic aberrations in the lithographic projection apparatus, particularly the projection system PL, and illumination symmetry and the presence of such aberrations may manifest themselves in a variation in the printed grating. In one example, an in-line method used in device manufacturing for measurements of line width, pitch, and critical dimension makes use of a technique known as “scatterometry”. For example, methods of scatterometry are described in Raymond et al., “Multiparameter Grating Metrology Using Optical Scatterometry”, J. Vac. Sci. Tech. B, Vol. 15, no. 2, pp. 361-368 (1997) and Niu et al., “Specular Spectroscopic Scatterometry in DUV Lithography”, SPIE, Vol. 3677 (1999), which are both incorporated by reference herein in their entireties. In scatterometry, light is reflected by periodic structures in the target, and the resulting reflection spectrum at a given angle is detected. The structure giving rise to the reflection spectrum is reconstructed, e.g. using Rigorous Coupled-Wave Analysis (RCWA) or by comparison to a library of patterns derived by simulation. Accordingly, the scatterometry data of the printed gratings is used to reconstruct the gratings. The parameters of the grating, such as line widths and shapes, may be input to the reconstruction process, performed by processing unit PU, from knowledge of the printing step and/or other scatterometry processes.

In some embodiments, beam splitter 414 can be further configured to receive diffraction radiation beam 419 and split diffraction radiation beam 419 into one or more radiation sub-beams, according to an embodiment. Diffraction radiation beam 419 can be split into diffraction radiation sub-beam 429, as shown in FIG. 4. Other diffraction radiation sub-beam are not shown in FIG. 4.

It should be noted that even though beam splitter 414 is shown to direct radiation sub-beam 415 towards alignment mark or target 418 and to direct diffracted radiation sub-beam 429 towards interferometer 426, the disclosure is not so limiting. It would be apparent to a person skilled in the relevant art that other optical arrangements may be used to obtain the similar result of illuminating alignment mark or target 418 on substrate 420 and detecting an image of alignment mark or target 418.

As illustrated in FIG. 4, interferometer 426 can be configured to receive radiation sub-beam 417 and diffracted radiation sub-beam 429 through beam splitter 414. In an example embodiment, diffracted radiation sub-beam 429 can be at least a portion of radiation sub-beam 415 that may be reflected from alignment mark or target 418. In an example of this embodiment, interferometer 426 comprises any appropriate set of optical-elements, for example, a combination of prisms that may be configured to form two images of alignment mark or target 418 based on the received diffracted radiation sub-beam 429. It should be appreciated that a good quality image need not be formed, but that the features of alignment mark 418 should be resolved. Interferometer 426 can be further configured to rotate one of the two images with respect to the other of the two images 180° and recombine the rotated and unrotated images interferometrically.

In some embodiments, detector 428 can be configured to receive the recombined image via interferometer signal 427 and detect interference as a result of the recombined image when alignment axis 421 of metrology apparatus 400 passes through a center of symmetry (not shown) of alignment mark or target 418. Such interference may be due to alignment mark or target 418 being 180° symmetrical, and the recombined image interfering constructively or destructively, according to an example embodiment. Based on the detected interference, detector 428 can be further configured to determine a position of the center of symmetry of alignment mark or target 418 and consequently, detect a position of substrate 420. According to an example, alignment axis 421 may be aligned with an optical beam perpendicular to substrate 420 and passing through a center of image rotation interferometer 426. Detector 428 can be further configured to estimate the positions of alignment mark or target 418 by implementing sensor characteristics and interacting with wafer mark process variations.

In a further embodiment, detector 428 can determine the position of the center of symmetry of alignment mark or target 418 by performing one or more of the following measurements:
1. measuring position variations for various wavelengths (position shift between colors);
2. measuring position variations for various orders (position shift between diffraction orders); and/or
3. measuring position variations for various polarizations (position shift between polarizations). This data may for example be obtained with any type of alignment sensor, for example a SMASH (SMart Alignment Sensor Hybrid) sensor, as described in U.S. Pat. No. 6,961,116 that employs a self-referencing interferometer with a single detector and four different wavelengths, and extracts the alignment signal in software, an ORION sensor, or Athena (Advanced Technology using High order ENhancement of Alignment), as described in U.S. Pat. No. 6,297,876, which directs each of seven diffraction orders to a dedicated detector, which are both incorporated by reference herein in their entireties.

In some embodiments, processor 432 receives information from detector 428. For example, processor 432 can be an overlay calculation processor. Processor 432 can construct a model of the product mark profile using the received information about the product mark. In either case, processor 432 constructs a model of the stacked product and overlay mark profile using or incorporating a model of the product mark profile. The stack model is then used to determine the overlay offset and minimizes the spectral effect on the overlay offset measurement. Processor 432 can create a basic correction algorithm based on the information received from detector 428, including but not limited to the optical state of the illumination beam, the alignment signals, associated position estimates, and the optical state in the pupil, image, and additional planes. The pupil plane is the plane in which the radial position of radiation defines the angle of incidence and the angular position defines the azimuth angle of the radiation. Processor 432 can utilize the basic correction algorithm to characterize the metrology apparatus 400 with reference to wafer marks and/or alignment marks 418.

In some embodiments, processor 432 can be further configured to determine printed pattern position offset error with respect to the sensor estimate for each mark based on the information received from detector 428. The information includes but is not limited to the product stack profile, measurements of overlay, critical dimension, and focus of each alignment marks or target 418 on substrate 420. Processor 432 can utilize a clustering algorithm to group the marks into sets of similar constant offset error, and create an alignment error offset correction table based on the information. The clustering algorithm may be based on overlay measurement, the position estimates, and additional optical stack process information associated with each set of offset errors. The overlay is calculated for a number of different marks, for example, overlay targets having a positive and a negative bias around a programmed overlay offset. The target that measures the smallest overlay is taken as reference (as it is measured with the best accuracy). From this measured small overlay, and the known programmed overlay of its corresponding target, the overlay error may be deduced. Table 1 illustrates how this may be performed. The smallest measured overlay in the example shown is −1 nm. However, this is in relation to a target with a programmed overlay of −30 nm. Consequently, the process has introduced an overlay error of 29 nm.

TABLE 1

| | | | | | | | |
|---|---|---|---|---|---|---|---|
| Programmed overlay | −70 | −50 | −30 | −10 | 10 | 30 | 50 |
| Measured overlay | −38 | −19 | −1 | 21 | 43 | 66 | 90 |
| Difference between | 32 | 31 | 29 | 31 | 33 | 36 | 40 |
| measured and | | | | | | | |
| programmed overlay | | | | | | | |
| Overlay error | 3 | 2 | — | 2 | 4 | 7 | 11 |

The smallest value may be taken to be the reference point and, relative to this, the offset may be calculated between measured overlay and that expected due to the programmed overlay. This offset determines the overlay error for each mark or the sets of marks with similar offsets. Therefore, in the Table 1 example, the smallest measured overlay was −1 nm, at the target position with programmed overlay of 30 nm. The difference between the expected and measured overlay at the other targets is compared to this reference. A table such as Table 1 may also be obtained from marks and target 418 under different illumination settings, the illumination setting, which results in the smallest overlay error, and its corresponding calibration factor, may be determined and selected. Following this, processor 432 can group marks into sets of similar overlay error. The criteria for grouping marks may be adjusted based on different process controls, for example, different error tolerances for different processes.

In some embodiments, processor 432 can confirm that all or most members of the group have similar offset errors, and apply an individual offset correction from the clustering algorithm to each mark, based on its additional optical stack metrology. Processor 432 can determine corrections for each mark and feed the corrections back to lithographic apparatus 100 or 100′ for correcting errors in the overlay, for example, by feeding corrections into the alignment apparatus 400.

Typically, ICs are built up layer by layer and can have 30 or more layers. On Product Overlay (OPO) is a measure of a lithographic apparatus's ability to fabricate these layers accurately on top of each other. Successive layers or multiple processes on the same layer must be accurately aligned to the previous layer. Otherwise, electrical contact between structures can be poor and the resulting devices may not perform to specification. Accurate alignment (e.g., decreased overlay error) can improve device yield and enable smaller product patterns to be fabricated. Measurement of the relative position of several alignment marks within a field can reduce and help correct OPO errors.

In order to control a lithographic process to place device features accurately on the substrate, one or more diffraction targets (e.g., alignment marks) can be provided on the substrate, and the lithographic apparatus can include one or more alignment sensors (e.g., forming a position measuring apparatus) configured to measure the positions of one or more diffraction targets in order to control a lithographic process to place device features accurately on the substrate. The accuracy of metrology sensors depends on aberration control in optical systems of the metrology sensor. With OPO values reaching 1 nm, budget allocations or tolerance for metrology sensors (e.g., alignment and overlay sensors) are in the sub-nanometer range. In some embodiments, the metrology sensor may need to have excellent wavefront control to achieve sub-nanometer tolerances, which makes it very expensive and time consuming to manufacture. For example, one or more flattening procedures (e.g., ion beam flattening (IBF), magneto-rheological fluid finishing (MRF)) or stress plates can be used to passively correct aberrations in an optical system. However, the IBF process is invasive and cannot be added to coated surfaces. Further, components may need to be taken out of the optical system, which may result in errors in the alignment of the optical system.

In some embodiments, a pattern may be transferred to the wavefront of an optical system by curing the adhesive (e.g., optical cement) used to bond the two surfaces with a modulated energy beam. In some aspects, optical cement between two surfaces is cured using a modulated energy beam having an illumination profile or pattern. In some aspects, the illumination profile is selected such as to compensate for optical aberrations in the optical system. In some aspects, the intensity of the modulated energy beam has a spatial variation.

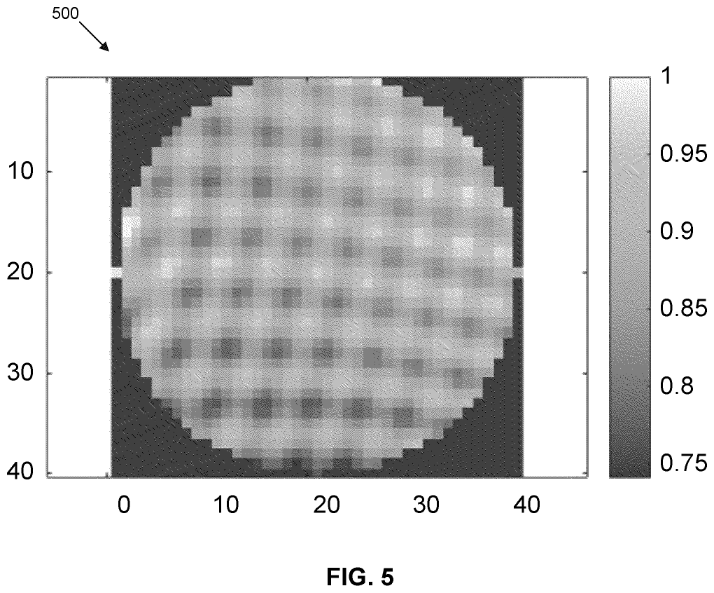

FIG. 5 is a schematic that illustrates an illumination profile 500, according to some embodiments. The illumination profile 500 can be used to cure wet adhesive between two parallel or curved surfaces. The illumination profile 500 can affect the rate at which the optical cement is cured.

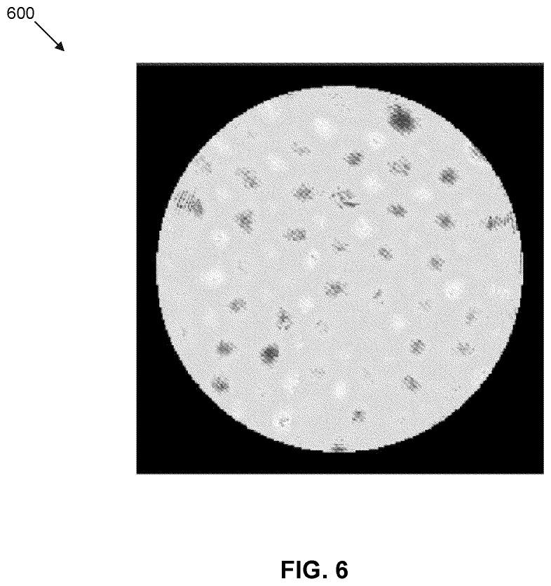

FIG. 6 is a schematic that illustrates a wavefront interferogram 600 resulting from curing optical cement using illumination profile 500, according to some embodiments. Wavefront interferogram 600 is measured at 635 nm. As shown by wavefront interferogram 600, the UV illumination is imprinted on the optical cement affecting the wavefront of the system at the operating wavelength. The transfer function of the illumination profile to the wavefront depends on illumination irradiance, optical cement thickness, and type of optical cement. Further, the wavefront interferogram 600 can be based on the stress between the optical elements and the optical cement. In some aspects, the stress can be modelled based on experimental data.

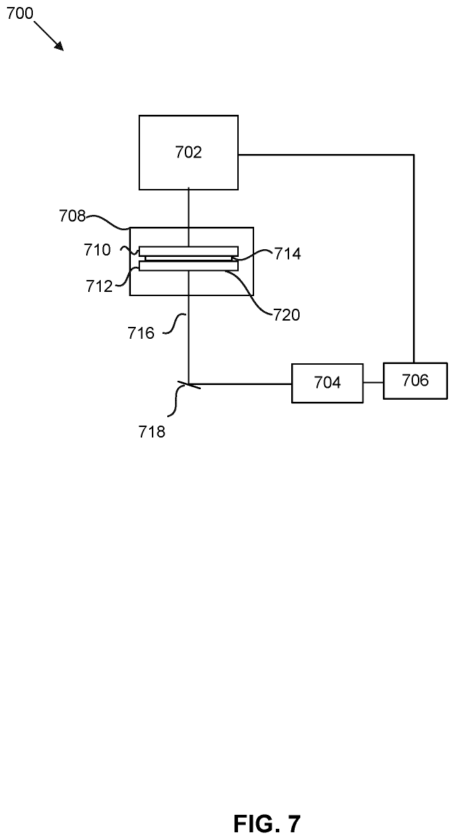

FIG. 7 is a schematic of a system 700, according to some embodiments. System 700 can comprise a processor 706, an illumination system 704, an optical device 708, and an optical system 702.

In some embodiments, optical device 708 can include a first optical element 710, a second optical element 712, and a layer of optical cement (i.e., adhesive, epoxy) 714 sandwiched between first optical element 710 and second optical element 712. First optical element 710 and second optical element 712 can be bonded by the layer of optical cement to form optical device 708. In some embodiments, a thickness of the optical cement layer is about 15 microns or lower, 10 microns or lower, or 5 microns or lower. In some aspects, first optical element 710 and/or second optical element 712 can be a transparent plate that includes planar and/or curved surfaces. In some embodiments, first optical element 710 and/or second optical element 712 can be a lens system (e.g., doublet, triplet), a prism, or the like. In some embodiments, optical device 708 can include a coated surface. For example, surface 720 of first optical element 712 can include an anti-reflective coating.

In some embodiments, optical aberrations of optical system 702 can be measured using interferometry techniques. In other embodiments, optical aberrations may be measured using a detector (e.g., a camera). In some aspects, the optical aberrations may be expressed in the form of Zernike polynomials. In some aspects, processor 706 can identify an illumination profile for a modulated energy beam 716 based on the measured optical aberrations. In some aspects, the illumination profile can be identified such as to compensate for the measured optical aberrations in optical system 702. In some aspects, the illumination profile is determined based on the optical aberrations, a thickness of the layer of optical cement 714, and a type of the optical cement.

In some embodiments, illumination system 704 is configured to irradiate a modulated energy beam 716 to achieve the predetermined profile. In some aspects, illumination system 704 can include a beam shaping device (e.g., microelectromechanical systems (MEMS) mirrors, digital light processing (DLP) mirrors) and a UV source. In some aspects, processor 706 can control the beam shaping device to obtain the predetermined profile. In other embodiments, the predetermined profile is obtained using interferometry techniques. In some embodiments, highly localized aberrations may be corrected using a beam shaping device having a high resolution. In some aspects, modulated energy beam 716 can be directed to optical device 708 via a reflective element 718 (e.g., a mirror). In some embodiments, the modulated energy beam 716 can cure the layer of optical cement 714.

In some embodiments, the optical cement and/or the optical elements may include an optically active substrate (e.g., crystalline quartz) and/or an optically active material.

In some embodiments, the aberrations may be measured and compensated for in-situ for a completely aligned optical system. In some embodiments, the aberrations of a subsystem of the optical system may be measured and compensated for as described further below.

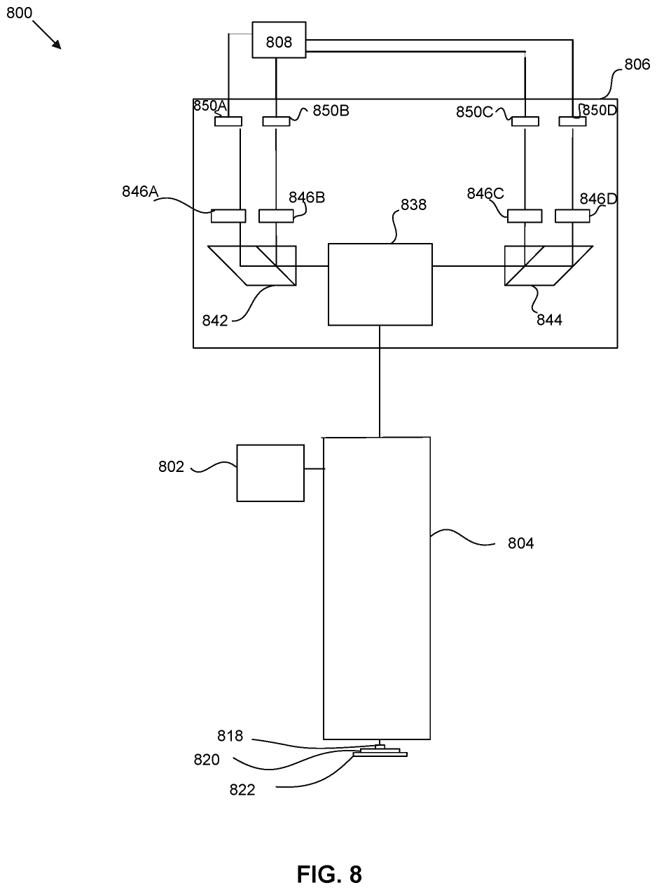

FIG. 8 shows a schematic of a system 800, according to some embodiments. In some embodiments, system 800 can also represent a more detailed view of inspection apparatus 400 (FIG. 4).

In some embodiments, system 800 includes an illumination system 802, an optical system 804, a detector system 806, and a processor 808.

FIG. 8 shows a non-limiting depiction of system 800 inspecting a target 818 (also “target structure”) on a substrate 820. The substrate 820 is disposed on a stage 822 that is adjustable (e.g., a support structure that can move).

In some embodiments, target 818 can comprise a diffractive structure. Target 818 can reflect, refract, diffract, scatter, or the like, radiation. For ease of discussion, and without limitation, radiation that interacts with a target will be termed scattered radiation throughout.

The detection system 806 can include a self-referencing interferometer 838 and one or more detectors. The scattered radiation can be passed through optical system 804 and to the self-referencing interferometer 838.

In one aspect, a further beam splitter 842 splits the optical signal into two paths A and B. One path can contain the sum of the two rotated fields, and the other can contain the difference. Similarly, a beam splitter 844 can split the optical signal into two paths C and D, each path representing the sum and the difference of the rotated fields. The radiation of each path A, B, C, and D can be collected by a respective lens assembly 846A, 846B, 846C, and 846D. Lens assembly 846A, 846B, 846C, and 846D can focus the radiation field into each detector 850A, 850B, 850C, and 850D respectively. Each detector can provide a time-varying signals (e.g., waveforms) synchronized with the physical scanning movement between the system 800 and the target structure 818. Signals from the detectors can be processed by processor 808.

In some embodiments, the optical aberrations of the detection system 806 can be compensated for by curing one or more layers of optical cements with a modulated energy beam to transfer the illumination profile to the wavefront of the detection system 806. In some aspects, optical cement between the one or more prisms of beam splitter 842 and/or beam splitter 844 can be cured using the modulated energy beam to achieve the illumination profile as described previously herein.

In some embodiments, optical aberrations in path A, in path B, in path C, and in path D can be compensated for using each of lens assembly 846A, 846B, 846C, and 846D, respectively. For example, optical aberrations in path A may be measured. Lens assembly 846A can include one or more lenses (not shown). The one or more lenses may be bonded together using a layer of optical cement. The optical cement is cured using the modulated energy beam. In some aspects, the optical aberrations in path A may be measured in-situ. In other words, the optical aberrations are determined while elements of system 800 are aligned.

In some embodiments, optical aberrations of detection system 806 are determined. In some aspects, self-referencing interferometer 838 can include one or more layers of optical cements cured using the modulated energy beam to achieve the illumination profile that compensates for the optical aberrations of detection system 806. In other embodiments, one or more prisms of self-referencing interferometer 838 can be bonded to a substrate (e.g., a glass substrate) using a layer optical cement cured using the modulated energy beam that has an illumination profile that compensates for the optical aberrations of detection system 806.

In other embodiments, an optical device (e.g., optical device 708 of FIG. 7) can be added in the optical path between optical system 804 and self-referencing interferometer 838 to compensate for the optical aberrations of detection system 806. In some embodiments, a compensating optic may be added in the optical path based on a desired compensation.

In some embodiments, the approaches described herein may be used to control aberrations in the order of 200 nm or less. For example, optical device 708 can be used in conjunction with other aberration techniques (e.g., IBF) to provide fine control of the wavefront in the optical system. In some embodiments, the approaches described herein provide an aberration control resolution from about 5 nm to about 10 nm.

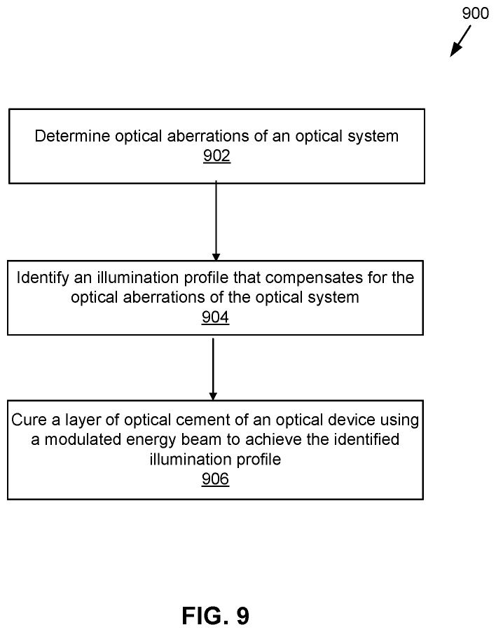

FIG. 9 shows method steps (e.g., using one or more processors) for performing a method 900 including functions described herein, according to some embodiments. The method 900 of FIG. 9 can be performed in any conceivable order and it is not required that all steps be performed. Moreover, the method steps of FIG. 9 described above merely reflect an example of steps and are not limiting.

Method 900 includes determining optical aberrations of an optical system, as illustrated in step 902. For example, optical aberrations of system 800 of FIG. 8 are measured.

The method also includes identifying an illumination profile that compensates for the optical aberrations of the optical system, as illustrated in step 904. In some aspects, the illumination profile can be determined using a feedback model between illumination profile and the final wavefront. (e.g., wavefront 600 in FIG. 6). In some aspects, the feedback model can be determined theoretically or experimentally.

The method also includes curing a layer of optical cement of an optical device using a modulated energy beam to achieve the identified illumination profile, as illustrated in step 906. In some aspects, the method also includes compensating for the determined optical aberrations of the optical system by disposing the optical device in an optical path of the optical system.

The embodiments may further be described using the following clauses:
1. A method, comprising:
   determining optical aberrations of an optical system;
   identifying, using processing circuitry, an illumination profile that compensates for the optical aberrations of the optical system; and
   curing a layer of optical cement of an optical device using a modulated energy beam to achieve the identified illumination profile.
2. The method of clause 1, further comprising:
   compensating for the determined optical aberrations of the optical system by disposing the optical device with the cured layer in an optical path of the optical system.
3. The method of clause 1, wherein the optical device comprises a first optical element and a second optical element; and
   wherein the optical layer of optical cement is deposited between the first optical element and the second optical element.
4. The method of clause 3, forming a lens using the first optical element and the second optical element.
5. The method of clause 1, wherein the curing of the layer of optical cement is performed after coating a surface of the optical device.
6. The method of clause 1, wherein the curing comprises using a modulated energy beam having a wavelength of the energy beam in the UV spectrum.
7. The method of clause 1, further comprising:
   controlling a birefringence of the optical system, wherein the optical device comprises an optically active material.
8. The method of clause 7, wherein the controlling of the birefringence of the optical system comprises using an optical cement including the optically active material.
9. The method of clause 1, further comprising:
   modulating the energy beam using a microelectromechanical systems (MEMS) device.
10. The method of clause 1, wherein identifying the illumination profile comprising:
   determining an irradiance of the beam based on a thickness of the layer of optical cement and a type of the optical cement.
11. The method of clause 10, wherein determining the irradiance of the beam is further based on a stress between a curved surface of the optical device and the layer of optical cement.
12. A system, comprising:
   an optical system having an optical device;
   a processor configured to
      determine optical aberrations of the optical system, and
      identify an illumination profile that compensates for the optical aberrations of; and
   an illumination system configured to
      generate an energy beam,
      modulate the energy beam with the illumination profile, and
      cure a layer of optical cement of the optical device of the optical system with the energy beam.
13. The system of clause 12, wherein the optical device comprises a first optical element and a second optical element; and
   wherein the optical layer of optical cement is deposited between the first optical element and the second optical element.
14. The system of clause 13, wherein the first optical element and the second optical element form a lens.
15. The system of clause 12, wherein the optical device comprises a coated surface.
16. The system of clause 12, wherein the optical device includes a curved surface.
17. The system of clause 12, wherein the illumination system comprises a microelectromechanical systems (MEMS) device to modulate the energy beam.
18. The system of clause 12, wherein the optical cement includes an optically active material.
19. A lithography apparatus comprising:
   an illumination apparatus configured to illuminate a pattern of a patterning device;
   a projection system configured to project an image of the pattern onto a substrate; and
   an optical system including
      an illumination system configured to generate an energy beam having an illumination profile determined based on optical aberrations of the optical system and to illuminate an optical device with the energy beam,
      the optical device deposited in an optical path of the optical system, wherein the optical device includes a layer of optical cement cured using the beam, and
      processing circuitry configured to determine the illumination profile based on the optical aberrations of the optical system.
20. The lithography apparatus of clause 19, wherein the optical device comprises an optically active material configured to control a birefringence of the optical system.

In some embodiments, the method includes controlling a birefringence of the optical system. In some aspects, the optical device comprises an optically active material. In some embodiments, a phase of the light passing through the optical device can be controlled using the illumination profile.

Although specific reference can be made in this text to the use of lithographic apparatus in the manufacture of ICs, it should be understood that the lithographic apparatus described herein may have other applications, such as the manufacture of integrated optical systems, guidance and detection patterns for magnetic domain memories, flat-panel displays, LCDs, thin-film magnetic heads, etc. The skilled artisan will appreciate that, in the context of such alternative applications, any use of the terms “wafer” or “die” herein can be considered as synonymous with the more general terms “substrate” or “target portion”, respectively. The substrate referred to herein can be processed, before or after exposure, in for example a track unit (a tool that typically applies a layer of resist to a substrate and develops the exposed resist), a metrology unit and/or an inspection unit. Where applicable, the disclosure herein can be applied to such and other substrate processing tools. Further, the substrate can be processed more than once, for example in order to create a multi-layer IC, so that the term substrate used herein may also refer to a substrate that already contains multiple processed layers.

Although specific reference may have been made above to the use of embodiments of the present disclosure in the context of optical lithography, it will be appreciated that the present disclosure can be used in other applications, for example imprint lithography, and where the context allows, is not limited to optical lithography. In imprint lithography a topography in a patterning device defines the pattern created on a substrate. The topography of the patterning device can be pressed into a layer of resist supplied to the substrate whereupon the resist is cured by applying electromagnetic radiation, heat, pressure or a combination thereof. The patterning device is moved out of the resist leaving a pattern in it after the resist is cured.

It is to be understood that the phraseology or terminology herein is for the purpose of description and not of limitation, such that the terminology or phraseology of the present disclosure is to be interpreted by those skilled in relevant art(s) in light of the teachings herein.

The term “substrate” as used herein describes a material onto which material layers are added. In some embodiments, the substrate itself can be patterned and materials added on top of it may also be patterned, or may remain without patterning.

Although specific reference can be made in this text to the use of the apparatus and/or system according to the present disclosure in the manufacture of ICs, it should be explicitly understood that such an apparatus and/or system has many other possible applications. For example, it can be employed in the manufacture of integrated optical systems, guidance and detection patterns for magnetic domain memories, LCD panels, thin-film magnetic heads, etc. The skilled artisan will appreciate that, in the context of such alternative applications, any use of the terms “reticle,” “wafer,” or “die” in this text should be considered as being replaced by the more general terms “mask,” “substrate,” and “target portion,” respectively.

While specific embodiments of the present disclosure have been described above, it will be appreciated that the present disclosure can be practiced otherwise than as described. The description is not intended to limit the present disclosure.

It is to be appreciated that the Detailed Description section, and not the Summary and Abstract sections, is intended to be used to interpret the claims. The Summary and Abstract sections may set forth one or more but not all exemplary embodiments of the present disclosure as contemplated by the inventor(s), and thus, are not intended to limit the present disclosure and the appended claims in any way.

The present disclosure has been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The foregoing description of the specific embodiments will so fully reveal the general nature of the present disclosure that others can, by applying knowledge within the skill of the art, readily modify and/or adapt for various applications such specific embodiments, without undue experimentation, without departing from the general concept of the present disclosure. Therefore, such adaptations and modifications are intended to be within the meaning and range of equivalents of the disclosed embodiments, based on the teaching and guidance presented herein.

The breadth and scope of protected subject matter should not be limited by any of the above-described exemplary embodiments, but should be defined only in accordance with the following claims and their equivalents.

1. A method, comprising:
determining optical aberrations of an optical system;
identifying, using processing circuitry, an illumination profile that compensates for the optical aberrations of the optical system; and
curing a layer of optical cement of an optical device using a modulated energy beam to achieve the identified illumination profile.

2. The method of claim 1, further comprising:
compensating for the determined optical aberrations of the optical system by disposing the optical device with the cured layer in an optical path of the optical system.

3. The method of claim 1, wherein the optical device comprises a first optical element and a second optical element; and
wherein the optical layer of optical cement is deposited between the first optical element and the second optical element.

4. The method of claim 3, forming a lens using the first optical element and the second optical element.

5. The method of claim 1, wherein the curing of the layer of optical cement is performed after coating a surface of the optical device.

6. The method of claim 1, wherein the curing comprises using a modulated energy beam having a wavelength of the energy beam in the UV spectrum.

7. The method of claim 1, further comprising:
controlling a birefringence of the optical system, wherein the optical device comprises an optically active material.

8. The method of claim 7, wherein the controlling of the birefringence of the optical system comprises using an optical cement including the optically active material.

9. The method of claim 1, further comprising:
modulating the energy beam using a microelectromechanical systems (MEMS) device.

10. The method of claim 1, wherein identifying the illumination profile comprising:
determining an irradiance of the beam based on a thickness of the layer of optical cement and a type of the optical cement.

11. The method of claim 10, wherein determining the irradiance of the beam is further based on a stress between a curved surface of the optical device and the layer of optical cement.

12. A system, comprising:
an optical system having an optical device;
a processor configured to
determine optical aberrations of the optical system, and
identify an illumination profile that compensates for the optical aberrations of; and
an illumination system configured to
generate an energy beam,
modulate the energy beam with the illumination profile, and
cure a layer of optical cement of the optical device of the optical system with the energy beam.

13. The system of claim 12, wherein the optical device comprises a first optical element and a second optical element; and
wherein the optical layer of optical cement is deposited between the first optical element and the second optical element.

14. The system of claim 13, wherein the first optical element and the second optical element form a lens.

15. The system of claim 12, wherein the optical device comprises a coated surface.

16. The system of claim 12, wherein the optical device includes a curved surface.

17. The system of claim 12, wherein the illumination system comprises a microelectromechanical systems (MEMS) device to modulate the energy beam.

18. The system of claim 12, wherein the optical cement includes an optically active material.
